(19) United States
(12) Patent Application Publication
(10) Pub. No.: US 2020/0208052 A1
(43) Pub. Date: Jul. 2, 2020

(54) ETCHANT COMPOSITION FOR ETCHING METAL FILM AND METHOD OF FORMING PATTERN USING THE SAME

(71) Applicant: SAMSUNG ELECTRONICS CO., LTD., Suwon-si (KR)

(72) Inventors: Kihun SONG, Suwon-si (KR); Jungmin OH, Incheon (KR); Hyosan LEE, Hwaseong-si (KR); Daehyuk CHUNG, Seoul (KR); Minjung KIM, Bucheon-si (KR); Hyojoong YOON, Iksan-si (KR)

(73) Assignee: DONGWOO FINE-CHEM Co., Ltd., Iksan-si (KR)

(21) Appl. No.: 16/728,276

(22) Filed: Dec. 27, 2019

(30) Foreign Application Priority Data
Dec. 27, 2018 (KR) 10-2018-0171078

(51) Int. Cl. C09K 13/06; H01L 21/311

(52) U.S. Cl. CPC C09K 13/06; H01L 21/31111

(57) ABSTRACT

An etchant composition for etching a metal film and a method of forming a pattern, the etchant composition including an acid etching agent, the acid etching agent including an inorganic acid or an organic acid; an auxiliary oxidant, the auxiliary oxidant including hydrogen peroxide or an amine oxide compound; and an organic solvent, the organic solvent including a compound having an unshared electron pair, and having a dielectric constant of about 17 to about 80.

### CROSS-REFERENCE TO RELATED APPLICATION

Korean Patent Application No. 10-2018-0171078, filed on Dec. 27, 2018, in the Korean Intellectual Property Office, and entitled: “Etchant Composition for Etching Metal Film and Method of Forming Pattern Using the Same,” is incorporated by reference herein in its entirety.

### BACKGROUND

### 1. Field

Embodiments relate to an etchant composition for etching a metal film and a method of forming a pattern using the same.

### 2. Description of the Related Art

In semiconductor devices, such as dynamic random access memory (DRAM), a NAND flash memory device, and a logic device, techniques for implementing high-speed operations while rapidly reducing critical dimensions (CDs) have been considered.

### SUMMARY

The embodiments may be realized by providing an etchant composition for etching a metal film, the etchant composition including an acid etching agent, the acid etching agent including an inorganic acid or an organic acid; an auxiliary oxidant, the auxiliary oxidant including hydrogen peroxide or an amine oxide compound; and an organic solvent, the organic solvent including a compound having an unshared electron pair, and having a dielectric constant of about 17 to about 80.

The embodiments may be realized by providing a method of forming a pattern, the method including forming an insulating film on a substrate, the insulating film including an opening; forming a metal pattern inside the opening; and partially etching an upper portion of the metal pattern using the etchant composition according to an embodiment.

The embodiments may be realized by providing a method of forming a pattern, the method including forming an insulating film on a substrate, the insulating film including an opening; forming a metal pattern inside the opening; and partially etching an upper portion of the metal pattern using an etchant composition, the etchant composition including an acid etching agent, an auxiliary oxidant that includes hydrogen peroxide or an amine oxide compound, and an organic solvent having a dielectric constant of about 17 to about 80 and that includes a compound having an unshared electron pair.

### BRIEF DESCRIPTION OF THE DRAWINGS

Features will be apparent to those of skill in the art by describing in detail exemplary embodiments with reference to the attached drawings in which:

FIGS. 1 to 3 illustrate schematic cross-sectional views of stages in a method of forming a pattern according to example embodiments; and

FIGS. 4 and 5 illustrate schematic cross-sectional views of stages in a method of forming a pattern according to some example embodiments.

### DETAILED DESCRIPTION

Embodiments provide an etchant composition. The etchant composition may include, e.g., an acid etching agent, an auxiliary oxidant, and an organic solvent, and may provide improved metal film etching uniformity. Also, embodiments provide a method of forming a pattern using the etchant composition.

In an implementation, the etchant composition may be used for a process of etching a low-resistance metal film (e.g., a cobalt (Co) film) to form gate electrodes and interconnections of semiconductor devices.

Hereinafter, embodiments will be described in detail.

<Etchant Composition for Etching a Metal Film>

An etchant composition for etching a metal film (hereinafter, abbreviated as an etchant composition) according to example embodiments may include, e.g., an acid etching agent, an auxiliary oxidant, and an organic solvent. In an implementation, the composition may further include water, e.g., a balance or an excess of water.

The acid etching agent may be used as a main etching agent utilizing an oxidation reaction of a low-resistance metal (e.g., cobalt (Co)). The acid etching agent may include an inorganic acid or an organic acid. As used herein, the term “or” is not an exclusive term, e.g., “A or B” would include A, B, or A and B. In an implementation, an acid having a high degree of acid dissociation may be used to implement a high etch rate. In an implementation, an acid having a pKa value of, e.g., about −2 to about 4 may be used.

In an implementation, the inorganic acid may include, e.g., phosphoric acid, pyro-phosphoric acid, poly phosphoric acid, sulfuric acid, nitric acid, hydrochloric acid, or perchloric acid.

In an implementation, a phosphoric acid compound, e.g., phosphoric acid, pyro-phosphoric acid, or polyphosphoric acid, may be used as the inorganic acid. In an implementation, inorganic acids, e.g., nitric acid, sulfuric acid, hydrochloric acid, or fluoric acid, may be excluded.

In an implementation, the organic acid may include, e.g., sulfonic acid compounds, such as methanesulfonic acid, ethanesulfonic acid, benzene sulfonic acid, and p-toluene sulfonic acid (PTSA), sulfobenzoic acid, sulfosuccinic acid, sulfophthalic acid, or sulfosalicylic acid; or carboxylic acid compounds, such as acetic acid, butanoic acid, citric acid, formic acid, caprylic acid, imminodiacetic acid, propenoic acid, isocitric acid, tartaric acid, glycolic acid, malonic acid, oxalic acid, pentanoic acid, phthalic acid, salicylic acid, benzoic acid, lactic acid, glyceric acid, succinic acid, or malic acid, and they may be used alone or in a combination of at least two thereof.

In an implementation, the acid etching agent may be included in an amount of, e.g., about 5 to about 12.5% by weight, based on a total weight of the etchant composition. Maintaining the amount of the acid etching agent at about 5% by weight or greater may help ensure that an etch rate is not reduced. Maintaining the amount of the acid etching agent at about 12.5% by weight or less may help ensure an etching uniformity or surface uniformity is not degraded.

The auxiliary oxidant may help adjust the density of a metal film oxidized by the acid etching agent and may help improve etching uniformity. In an implementation, a pH value of the etchant composition may be adjusted by the auxiliary oxidant. For example, the pH value of the etchant composition may be adjusted within the range of about 3 to about 6. For example, the pH value of the etchant composition may be adjusted within the range of about 5 to about 6. In this case, more uniform etching characteristics may be realized by adjusting the density of the oxidized metal film (e.g., a cobalt oxide film).

In an implementation, the auxiliary oxidant may include hydrogen peroxide or an amine oxide compound. In an implementation, the amine oxide compound may be used to implement a fine metal pattern under milder etching conditions.

In an implementation, the amine oxide compound may be, e.g., represented by the following Formula 1.

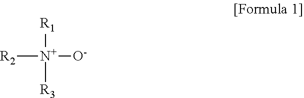

In Formula 1, R₁, R₂, and R₃ may each independently be, e.g., a C1 to C4 alkyl group or a hetero alkyl group. In an implementation, R₁, R₂, and R₃ may be separate, or two of R₁, R₂, and R₃ may form a hetero ring together with a nitrogen atom (e.g., the central nitrogen atom of Formula 1).

In an implementation, the amine oxide compound may include, e.g., N-ethylmorpholine-N-oxide (NMMO), trimethylamine-N-oxide, triethylamine-N-oxide, pyridine-N-oxide, 4-nitropyridine-N-oxide, N-ethylmorpholine-N-oxide, N-methylpyrrolidine-N-oxide, N-ethylpyrrolidine-N-oxide, or the like. In an implementation, they may be used alone or in a combination of at least two thereof.

In an implementation, the auxiliary oxidant may be included, in an amount of, e.g., about 1 to about 10% by weight, based on the total weight of the etchant composition. Within the content range of the auxiliary oxidant, sufficient metal-film etching capability may be ensured and an increase in surface roughness may be inhibited.

The organic solvent may include a compound that may facilitate control of the oxidation of a metal (e.g., cobalt) or a dissociation rate of the acid etching agent. For example, the organic solvent may be selected to help control a degree of dissociation of the acid etching agent while inhibiting an excessive increase in etch rate.

In an implementation, the organic solvent may include or may be a compound having a dielectric constant of, e.g., about 17 to about 80 (e.g., the organic solvent may have a dielectric constant of about 17 to about 80). Maintaining the dielectric constant of the organic solvent at about 17 or greater may help ensure that a sufficient degree of dissociation of the acid etching agent is achieved. Maintaining the dielectric constant of the organic solvent at about 80 or less may facilitate adjusting of the etching uniformity.

In an implementation, the organic solvent may have a dielectric constant of about 30 to about 70.

In an implementation, the organic solvent may include a compound including unshared electron pairs, e.g., nitrogen (N), oxygen (O), or sulfur (S). The unshared electron pair may solventize cobalt ions through ligand bonding. For example, cobalt ions oxidized by the acid etching agent may be coordinately bonded by the organic solvent and stabilized. For example, stable etching uniformity may be ensured while maintaining a proper etch rate.

In an implementation, the organic solvent may include, e.g., dimethyl sulfoxide, dimethylsulfone, diethylsulfone, methylsulfolane, sulfolane, γ-butyrolactone, δ-valerolactone, diethyl ketone, propylene carbonate, ethyl acetate, diethyl acetamide, monomethyl ether acetate, 1,3-dimethyl-2-imidazolidinone, or diethylene glycol.

In an implementation, the organic solvent may be included in an amount of, e.g., about 65 to about 85% by weight, based on the total weight of the etchant composition. Within the content range of the organic solvent, etching uniformity may be improved while maintaining a proper etch rate, and surface roughness may be reduced.

The etchant composition may include water. In an implementation, an excess amount of water or a residual amount of water may be included. As used herein, the term “balance amount” or “residual amount” may refer to a variable amount that depends on the addition of a component or an agent. For example, the term “balance amount” or “residual amount” may refer to the remaining amount except the acid etching agent, the auxiliary oxidant, and the organic solvent, which are described above, or the remaining amount except the acid etching agent, the auxiliary oxidant, the organic solvent, and other additives.

In an implementation, the water may be included in an amount of about 1 to 15% by weight, based on the total weight of the etchant composition. Maintaining the amount of the water at about 15% by weight or less may help ensure that etching control performance caused by the organic solvent is not degraded. In an implementation, the content of the water may be, e.g., about 5 to about 10% by weight.

In an implementation, the etchant composition may further include an additive. In an implementation, the additive may be included within a range that does not inhibit the etching performance and etching control performance of the acid etching agent, the auxiliary oxidant, and/or the organic solvent. In an implementation, the additive of the etching composition may include, e.g., an etching enhancer, a surfactant, an antifoaming agent, or the like.

In an implementation, the etchant composition may not include nitric acid. In this case, etching non-uniformity, which could be caused by an excessive increase in the etch rate of a metal nitride film or a metal film due to nitric acid, may be prevented.

In an implementation, the etchant composition may also not include sulfuric acid or a fluorine-containing compound (e.g., fluoric acid). In this case, an environmental damage due to sulfuric acid and the etching damage of an insulating film (e.g., a silicon oxide film) due to fluorine may be prevented.

In an implementation, when the etching composition does not include nitric acid and/or sulfuric acid, process failures due to an exothermic reaction may be prevented after an etching process, e.g., during a rinse process using an isopropyl alcohol (IPA) cleaning solution. For example, the etching process and the rinse process may be performed in a substantially single process or a continuous process (e.g., in the same chamber).

The etchant composition according to an embodiment may be used to finely etch the cobalt film. The etchant composition may be effectively applied to the formation of a uniform pattern while inhibiting an increase in the surface roughness of the cobalt film.

In an implementation, the etchant composition may provide an etch rate of about 40 Å/min to about 150 Å/min, e.g., about 80 Å/min to about 100 Å/min, with respect to the cobalt film, at a temperature of about 60° C. For example, a fine etching process may be effectively performed using the etchant composition under mild conditions for the cobalt film.

In an implementation, the etchant composition may be used to selectively etch the metal film, e.g., the cobalt film, while preventing the etching of a metal nitride film including titanium nitride (TiN).

<Method of Forming a Pattern>

FIGS. 1 to 3 illustrate schematic cross-sectional views of stages in a method of forming a pattern according to example embodiments.

Referring to FIG. 1, an insulating film 110 may be formed on a substrate 100.

The substrate 100 may include a semiconductor material, e.g., single crystalline silicon or a single crystalline germanium, or polysilicon.

The insulating film 110 may include an insulating material, e.g., silicon oxide, silicon nitride, silicon oxynitride, or polysiloxane. In an implementation, the insulating film 110 may be formed using a chemical vapor deposition (CVD) process, a sputtering process, a physical vapor deposition (PVD) process, or an atomic layer deposition (ALD) process.

The insulating film 110 may be partially etched to form an opening 115 in the insulating film 110. In an implementation, a top surface of the substrate 100 may be exposed through the opening 115. In an implementation, a lower conductive pattern and a lower insulating film may be formed under the substrate 100 and the insulating film 110. In this case, a top surface of the lower conductive pattern may be exposed through the opening 115.

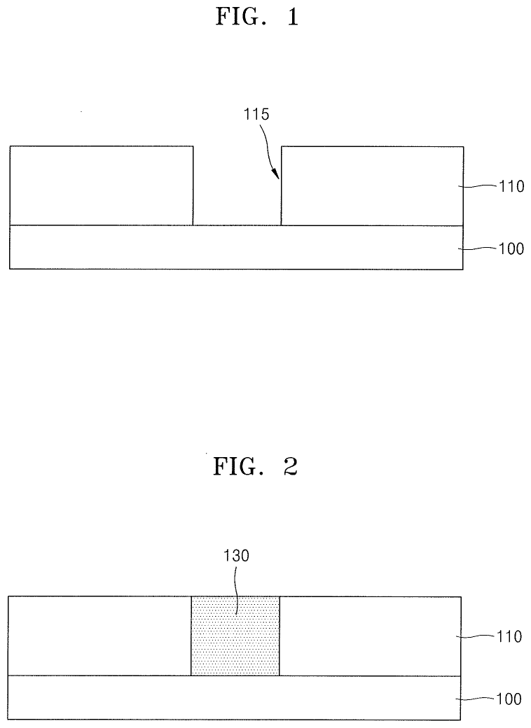

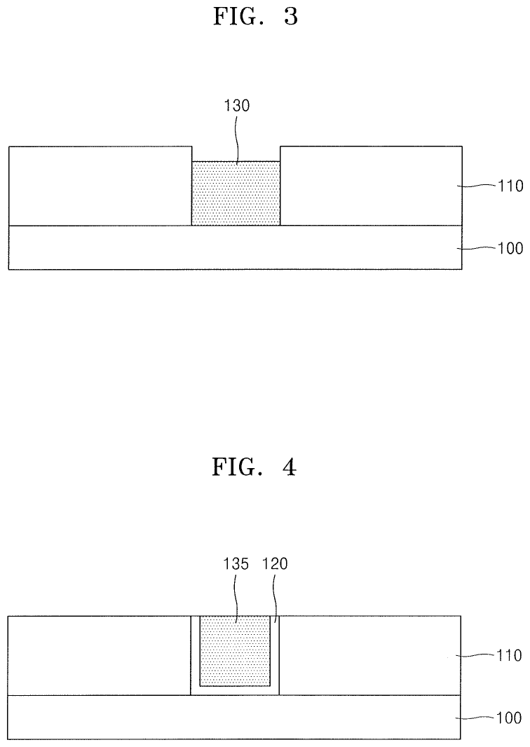

Referring to FIG. 2, a metal pattern 130 may be formed inside the opening 115. In an implementation, a metal film including cobalt (hereinafter, a cobalt film) may be formed on the insulating film 110 and the substrate 100 using a sputtering process to sufficiently fill the opening 115. Thereafter, an upper portion of the cobalt film may be planarized using, for example, a chemical mechanical polishing (CMP) process, so that a top surface of the insulating film 110 is exposed, thereby forming the metal pattern 130.

Referring to FIG. 3, an upper portion of the metal pattern 130 may be partially etched using the etchant composition according to the example embodiments described above.

For example, the metal pattern 130 may be recessed with respect to a sidewall of the insulating film 110 such that a top surface of the metal pattern 130 is located under the top surface of the insulating film 110 (e.g., the top surface of the metal pattern 130 may be closer to the substrate 100 than the top surface of the insulating film 110 is to the substrate 100).

As described above, the etchant composition may provide improved surface uniformity while maintaining a proper etch rate with respect to the cobalt film even under relatively low temperature conditions. Accordingly, for example, during a nanoscale semiconductor interconnection process, an interconnection isolation process may be performed with high reliability by finely etching the upper portion of the metal pattern 130.

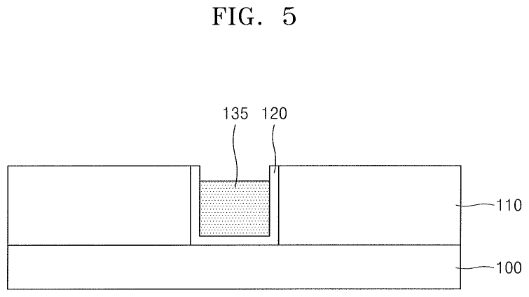

FIGS. 4 and 5 illustrate schematic cross-sectional views of stages in a method of forming a pattern according to some example embodiments.

Referring to FIG. 4, a barrier pattern 120 and a metal pattern 135 may be sequentially formed inside the opening 115, which is described with reference to FIG. 1.

In an implementation, a barrier film including a metal nitride and a metal film (e.g., a cobalt film) may be sequentially formed to fill the opening 115.

The barrier film may be continuously and conformally formed along the top surface of the insulating film 110 and a sidewall and a bottom surface of the opening 115. In an implementation, the barrier film may include titanium nitride (TiN) and be formed using a sputtering process, an ALD process, and/or a CVD process. The metal film may be formed on the barrier film to fill the remaining portion of the opening 115.

Subsequently, upper portions of the metal film and the barrier film may be planarized using a CMP process so that a top surface of the insulating film 110 is exposed. For example, a metal pattern 135 and a barrier pattern 120 may be respectively formed by planarizing the metal film and the barrier film. The diffusion of materials between the metal pattern 135 and the insulating film 110 may be prevented by the barrier pattern 120.

Referring to FIG. 5, an upper portion of the metal pattern 135 may be partially removed using the etchant composition according to the example embodiments described above.

In an implementation, the etchant composition may have an etch selectivity with respect to the cobalt film. For example, the barrier pattern 120 may not be substantially etched, and only the upper portion of the metal pattern 135 may be selectively etched.

After the etching process described above, a rinse process for removing the etching residue may be further performed. In an implementation, the rinse process may be performed using a cleaning solution including isopropyl alcohol (IPA).

In an implementation, the etchant composition may not include nitric acid, sulfuric acid, fluoric acid, or the like and process failures (due to an exothermic reaction of IPA with acid) may be prevented. For example, the etching process and the rinse process may be performed in a continuous process or in a single process (e.g., in the same process chamber).

The etching process may be performed under a relatively low-temperature condition of, e.g., about 70° C. or lower or about 60° C. or lower. For example, process failures that occur in a high-temperature etching process may also be reduced.

An etchant composition for etching a metal film, according to embodiments, may include, e.g., an acid etching agent, an auxiliary oxidant, and an organic solvent. The organic solvent may be selected to help control a dissolution rate of a metal (e.g., cobalt) to be etched and to help implement relatively mild etching conditions. For example, a fine metal pattern having a reduced surface roughness and a substantially seamless surface profile may be formed.

In an implementation, surface roughness may be relatively precisely controlled using an amine oxide compound as the auxiliary oxidant.

Logic interconnections of a semiconductor device, such as cobalt nanoscale interconnections, may be formed with high reliability by using the etchant composition.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES AND COMPARATIVE EXAMPLES

Components described in the following Table 1 (Examples) and Table 2 (Comparative Examples) were mixed at contents (wt %) corresponding thereto and a balance amount of water was included in the mixtures to prepare etchant compositions of the Examples and Comparative Examples.

### Experimental Example 1: Estimation of Etching Characteristics of a Cobalt Film

(1) Estimation of Etch Rate

Samples were prepared by cutting a silicon wafer on which a cobalt film was deposited to a thickness of about 350 Å, to a size of 2 cm×2 cm. The sample was immersed in the etchant compositions of respective ones of the Examples and Comparative Examples for about 1 minute in a bath maintained at a temperature of about 60° C. Thereafter, the samples were taken out, rinsed with water, and dried using N₂ gas. A thickness of the etched cobalt films was measured using a scanning electron microscope (SEM), and an etch rate was calculated using a variation in initial film thickness of the cobalt film. Estimation criteria are as follows.

<Estimation Criteria>

⊚: etch rate of 80 Å/min or higher

σ: etch rate of 40 Å/m or greater and less than 80 Å/min

Δ: etch rate less than 40 Å/min and greater than 0 Å/min

x: Unetched

(2) Estimation of Etching Uniformity

A variation in the surface roughness of the cobalt film of the sample etched as described above was analyzed using an atomic force microscope (AFM). Estimation criteria are as follows.

<Estimation Criteria>

⊚: Root mean square (RMS) of less than 10 Å

◯: RMS of 10 Å or greater and less than 15 Å

Δ: RMS of 15 Å or greater and less than 20 Å

x: RMS of 20 Å or greater

Estimation results are shown in the following Tables 1 and 2.

TABLE 1

| | Acid etching | Auxiliary | Organic | | Etch | Etching |
|---|---|---|---|---|---|---|
| | agent | oxidant | solvent | Other | rate | uniformity |
| Example 1 | 10 (PA) | 0.5 (A-1) | 75 (DMSO) | — | ⊚ | Δ |
| Example 2 | 10 (PA) | 1 (A-1) | 75 (DMSO) | — | ⊚ | ◯ |
| Example 3 | 10 (PA) | 3 (A-1) | 75 (DMSO) | — | ⊚ | ◯ |
| Example 4 | 10 (PA) | 5 (A-1) | 75 (DMSO) | — | ⊚ | ⊚ |
| Example 5 | 10 (PA) | 7 (A-1) | 75 (DMSO) | — | ◯ | ◯ |
| Example 6 | 10 (PA) | 10 (A-1) | 75 (DMSO) | — | ◯ | ◯ |
| Example 7 | 10 (PA) | 13 (A-1) | 75 (DMSO) | — | ◯ | Δ |
| Example 8 | 10 (PA) | 5 (A-2) | 75 (DMSO) | — | ⊚ | ◯ |
| Example 9 | 10 (PA) | 5 (A-3) | 75 (DMSO) | — | ⊚ | ◯ |
| Example 10 | 10 (PA) | 5 (A-4) | 75 (DMSO) | — | ⊚ | ⊚ |
| Example 11 | 10 (PA) | 5 (A-5) | 75 (DMSO) | — | ⊚ | ◯ |
| Example 12 | 10 (PA) | 5 (A-1) | 75 (DMSO) | — | ⊚ | ◯ |
| | | 1 (A-2) | | | | |
| Example 13 | 10 (PA) | 5 (A-1) | 75 (DMSO) | — | ⊚ | ⊚ |
| | | 3 (A-2) | | | | |
| Example 14 | 10 (PA) | 5 (A-1) | 75 (DMSO) | — | ⊚ | ◯ |
| | | 5 (A-2) | | | | |
| Example 15 | 2.5 (PA) | 5 (A-1) | 75 (DMSO) | — | Δ | Δ |
| Example 16 | 5 (PA) | 5 (A-1) | 75 (DMSO) | — | Δ | Δ |
| Example 17 | 12.5 (PA) | 5 (A-1) | 75 (DMSO) | — | ⊚ | ◯ |
| Example 18 | 15 (PA) | 5 (A-1) | 75 (DMSO) | — | ⊚ | Δ |
| Example 19 | 10 (pPA) | 5 (A-1) | 75 (DMSO) | — | ⊚ | ⊚ |
| Example 20 | 10 (MSA) | 5 (A-1) | 75 (DMSO) | — | ◯ | Δ |
| Example 21 | 10 (FA) | 5 (A-1) | 75 (DMSO) | — | ⊚ | Δ |
| Example 22 | 10 (AA) | 5 (A-1) | 75 (DMSO) | — | Δ | Δ |
| Example 23 | 10 (PA) | 5 (A-1) | 50 (DMSO) | — | ⊚ | Δ |
| Example 24 | 10 (PA) | 5 (A-1) | 60 (DMSO) | — | ⊚ | Δ |
| Example 25 | 10 (PA) | 5 (A-1) | 85 (DMSO) | — | ◯ | ◯ |
| Example 26 | 10 (PA) | 2.5 (A-1) | 87.5 (DMSO) | — | Δ | ◯ |
| Example 27 | 10 (PA) | 5 (A-1) | 75 (GBL) | — | ◯ | ◯ |
| Example 28 | 10 (PA) | 5 (A-1) | 75 (DEK) | — | ◯ | Δ |
| Example 29 | 10 (PA) | 5 (A-1) | 75 (EG) | — | ◯ | ◯ |
| Example 30 | 10 (PA) | 5 (A-1) | 75 (PC) | — | ⊚ | ◯ |
| Example 31 | 10 (PA) | 5 (A-5) | 85 (DMSO) | — | Δ | ◯ |

TABLE 2

| | Acid etching | Auxiliary | Organic | | Etch | Etching |
|---|---|---|---|---|---|---|
| | agent | agent | solvent | Other | rate | uniformity |
| Comparative | — | 5 (A-1) | 75 (DMSO) | — | X | ◯ |
| Example 1 | | | | | | |
| Comparative | 10 (PA) | 5 (A-1) | — | — | ⊚ | X |
| Example 2 | | | | | | |
| Comparative | 10 (PA) | — | 75 (DMSO) | — | ⊚ | X |
| Example 3 | | | | | | |
| Comparative | 10 (PA) | — | 75 (DMSO) | 5 (B-1) | ◯ | X |
| Example 4 | | | | | | |
| Comparative | 10 (PA) | — | 75 (DMSO) | 5 (B-2) | ◯ | X |
| Example 5 | | | | | | |
| Comparative | 10 (PA) | — | 75 (DMSO) | 5 (B-3) | ◯ | X |
| Example 6 | | | | | | |
| Comparative | 10 (PA) | — | 75 (DMSO) | 5 (B-4) | ◯ | X |
| Example 7 | | | | | | |
| Comparative | 10 (PA) | — | 75 (DMSO) | 5 (B-5) | ⊚ | X |
| Example 8 | | | | | | |
| Comparative | 10 (PA) | 5 (A-1) | 75 (PG) | — | X | ⊚ |
| Example 9 | | | | | | |

Specific component names described in Tables 1 and 2 are as follows.

Acid Etching Agent

1) PA: phosphoric acid (pKa=2.2)

2) pPA: pyro-phosphoric acid (pKa=0.9)

3) MSA: methanesulfonic acid (pKa=−1.2)

4) FA: formic acid (pKa=3.8)

5) AA: acetic acid (pKa=4.8)

Auxiliary Oxidant

1) A-1: N-methylmorpholine N-oxide

2) A-2: hydrogen peroxide (H₂O₂)

3) A-3: N-ethylmorpholine N-oxide (NMMO)

4) A-4: pyridine-N-oxide

5) A-5: trimethylamine N-oxide (TMANO)

Organic Solvent

1) DMSO: dimethyl sulfoxide (dielectric constant (e): 46.7)

2) GBL: γ-butyrolactone (dielectric constant: 39)

3) DEK: diethyl ketone (dielectric constant: 17.3)

4) EG: ethylene glycol (dielectric constant: 38.7)

5) PC: propylene carbonate (dielectric constant: 64.9)

6) PG: propylene glycol (dielectric constant: 8.3)

Other Components

1) B-1: NEM: N-ethylmorpholine (NEM)

2) B-2: 4-aminomorpholine

3) B-3: N-(2-hydroxyethyl) morpholine

4) B-4: monoisopropanolamine (MIPA)

5) B-5: ammonium fluoride

Referring to Tables 1 and 2, in the Examples (using the acid etching agent, the auxiliary oxidant, and the organic solvent as described above), etching uniformity was generally improved while ensuring a sufficient etch rate of the cobalt film, as compared with the Comparative Examples.

In Comparative Examples 4 to 8 (using an amine compound or morpholine compound instead of an amine oxide compound as an auxiliary oxidant), etching uniformity was degraded. In Comparative Example 9 (using PG having an excessively low dielectric constant as the organic solvent), an etch rate was excessively reduced.

### Experimental Example 2: Comparison of Etching Characteristics of a Tungsten (W) Film and a Cobalt (Co) Film

An etch rate and etching uniformity were evaluated using the etchant composition of Example 4 in the same manner as in Experimental Example 1. The evaluation results are shown in the following Table 3.

TABLE 3

| | Etch rate | Etching uniformity |
|---|---|---|
| Etching of Co film | ⊚ | ⊚ |
| Etching of W film | ◯ | Δ |

Referring to Table 3, it may be seen that the etchant composition according to Example 4 was effectively applied to the etching of a cobalt film, and provided excellent etching characteristics and high reliability (as compared to etching of a W film).

By way of summation and review, interconnections formed during a back-end process of semiconductor devices may use low-resistance metals, etchant compositions should be capable of finely controlling the etching of the low-resistance metals.

As CDs of fine metal interconnections are reduced, the operating performance of the fine metal interconnections could be degraded even due to minute non-uniformity of pattern profiles, such as the occurrence of seams and an increase in surface roughness.

For example, an etchant composition may be capable of improving etching uniformity while maintaining a predetermined etch rate. Also, the etchant composition may substantially and selectively etch only a metal film.

For example, an etchant composition for forming a metal pattern may be considered. However, it could be difficult to apply the etchant composition to a process of forming a nanoscale fine pattern with improved uniformity.

One or more embodiments may provide an etchant composition for etching a metal film, which includes an oxidative component.

One or more embodiments may provide an etchant composition for etching a metal film, which provides improved etching stability and etching uniformity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An etchant composition for etching a metal film, the etchant composition comprising:
an acid etching agent, the acid etching agent including an inorganic acid or an organic acid;
an auxiliary oxidant, the auxiliary oxidant including hydrogen peroxide or an amine oxide compound; and
an organic solvent, the organic solvent:
including a compound having an unshared electron pair, and
having a dielectric constant of about 17 to about 80.

2. The etchant composition as claimed in claim 1, wherein the acid etching agent includes an acid having a pKa value of about −2 to about 4.

3. The etchant composition as claimed in claim 1, wherein the acid etching agent includes phosphoric acid, pyro-phosphoric acid, or polyphosphoric acid.

4. The etchant composition as claimed in claim 1, wherein:
the auxiliary oxidant includes the amine oxide compound, the amine oxide compound being represented by the following Formula 1: 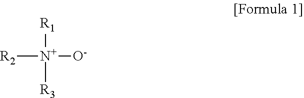
in Formula 1, R₁, R₂, and R₃ are each independently a C1 to C4 alkyl group or a hetero alkyl group, and
R₁, R₂, and R₃ are separate or two of R₁, R₂, and R₃ form a hetero ring together with a nitrogen atom.

5. The etchant composition as claimed in claim 1, wherein the auxiliary oxidant includes N-methylmorpholine-N-oxide (NMMO), trimethylamine-N-oxide, triethylamine-N-oxide, pyridine-N-oxide, 4-nitropyridine-N-oxide, N-ethylmorpholine-N-oxide, N-methylpyrrolidine-N-oxide, or N-ethylpyrrolidine-N-oxide.

6. The etchant composition as claimed in claim 1, wherein the organic solvent has a dielectric constant of about 30 to about 70.

7. The etchant composition as claimed in claim 1, wherein the organic solvent includes dimethyl sulfoxide, dimethylsulfone, diethylsulfone, methylsulfolane, sulfolane, γ-butyrolactone, δ-valerolactone, diethyl ketone, propylene carbonate, ethyl acetate, diethyl acetamide, monomethyl ether acetate, 1,3-dimethyl-2-imidazolidinone, or diethylene glycol.

8. The etchant composition as claimed in claim 1, further comprising water.

9. The etchant composition as claimed in claim 8, wherein the composition includes:
about 5 to about 12.5% by weight of the acid etching agent;
about 1 to about 10% by weight of the auxiliary oxidant;
about 65 to about 85% by weight of the organic solvent; and
about 1 to about 15% by weight of water,
all wt % based on a total weight of the etchant composition.

10. The etchant composition as claimed in claim 1, wherein the metal film includes cobalt (Co).

11. The etchant composition as claimed in claim 10, wherein the etchant composition exhibits an etch rate of the metal film that includes cobalt of about 40 Å/min to about 150 Å/min at a temperature of 60° C.

12. The etchant composition as claimed in claim 1, wherein the etchant composition does not include sulfuric acid, does not include nitric acid, does not include hydrochloric acid, and does not include fluoric acid.

13. A method of forming a pattern, the method comprising:
forming an insulating film on a substrate, the insulating film including an opening;
forming a metal pattern inside the opening; and
partially etching an upper portion of the metal pattern using the etchant composition as claimed in claim 1.

14. The method as claimed in claim 13, wherein the metal pattern includes cobalt (Co).

15. The method as claimed in claim 13, further comprising forming a barrier film that includes a metal nitride on an inner wall of the opening, prior to forming the metal pattern.

16. The method as claimed in claim 13, wherein the acid etching agent includes an acid having a pKa value of about −2 to about 4.

17. The method as claimed in claim 13, wherein:
the auxiliary oxidant includes the amine oxide compound, the amine oxide compound being represented by the following Formula 1: 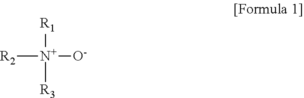
in Formula 1, R₁, R₂, and R₃ are each independently a C1 to C4 alkyl group or a hetero alkyl group, and
R₁, R₂, and R₃ are separate or two of R₁, R₂, and R₃ form a hetero ring together with a nitrogen atom.

18. A method of forming a pattern, the method comprising:
forming an insulating film on a substrate, the insulating film including an opening;
forming a metal pattern inside the opening; and
partially etching an upper portion of the metal pattern using an etchant composition, the etchant composition including an acid etching agent, an auxiliary oxidant that includes hydrogen peroxide or an amine oxide compound, and an organic solvent having a dielectric constant of about 17 to about 80 and that includes a compound having an unshared electron pair.

19. The method as claimed in claim 18, wherein the metal pattern includes cobalt (Co).

20. The method as claimed in claim 18, further comprising forming a barrier film that includes a metal nitride on an inner wall of the opening, prior to forming the metal pattern.
